(19) United States
(12) Patent Application Publication
(10) Pub. No.: US 2014/0220728 A1
(43) Pub. Date: Aug. 7, 2014

(54) METHODS OF FORMING SEMICONDUCTOR FILMS INCLUDING I2-II-IV-VI4 AND I2-(II,IV)-IV-VI4 SEMICONDUCTOR FILMS AND ELECTRONIC DEVICES INCLUDING THE SEMICONDUCTOR FILMS

(71) Applicants: Hugh Hillhouse, Seattle, WA (US); Wooseok Ki, San Ramon, CA (US)

(72) Inventors: Hugh Hillhouse, Seattle, WA (US); Wooseok Ki, San Ramon, CA (US)

(21) Appl. No.: 14/000,183

(22) PCT Filed: Feb. 17, 2012
(86) PCT No.: PCT/US2012/025706

§ 371 Date: Jan. 8, 2014

Related U.S. Application Data
(60) Provisional application No. 61/444,398, filed on Feb. 18, 2011.

(51) Int. Cl. H01L 31/18; H01L 21/02

(52) U.S. Cl. CPC H01L 31/18; H01L 21/02568
USPC 438/95; 438/104

(57) ABSTRACT

Embodiments of the present invention generally include methods for forming semiconductor films having nominal I₂-II-IV-VI₄ stoichiometry, such as CZTS or CZTSSe, using a solution of including sources of the I, II, IV, and VI elements in a liquid solvent. Precursors may be mixed in the solvent to form the solution. Metal halide salts may be used as precursors in some examples. The solution may be coated onto a substrate and annealed to yield the semiconductor film. In some examples, the source of the ‘I’ and ‘IV’ elements may contain the elements in a +2 oxidation state, while the semiconductor film may contain the ‘I’ element in a +1 oxidation state and the ‘IV’ element in a +4 oxidation state. Examples may be used to provide I₂-(II,IV)-IV-VI₄ films.

### CROSS-REFERENCE TO RELATED APPLICATION(S)

This application claims priority from PCT patent application PCT/US2012/025706, filed Feb. 17, 2012, which claims the benefit of the filing date of U.S. Provisional Application 61/444,398, filed Feb. 18, 2011. These applications are hereby incorporated by reference in their entirety.

### TECHNICAL FIELD

Examples described herein may relate to methods of making semiconductor materials, semiconductor material compositions, and devices including the semiconductor materials. Semiconductor materials described herein include thin films with nominal I₂-II-IV-VI₄ stoichiometry, including but not limited to films of CZTS or CZTSSe (e.g. Cu₂ZnSnS₄ or Cu₂ZnSn(S,Se)₄).

### BACKGROUND

Thin film semiconductor materials find use in a variety of applications, including photovoltaic (PV) devices. Thin film solar cells of suitable efficiency have been fabricated of CuInGaSe₂ (CIGSe) and CdTe. However, price volatility issues (e.g. with In and Ga), abundance problems (with In and Te, which are rare elements), and potential environmental problems (with Cd) may limit the practical use of these thin films.

Thin films of Cu₂ZnSnS₄ and Cu₂ZnSnSe₄ have also been used to fabricate solar cells. The Earth-abundant, non-toxic nature of these films as well as their electronic band gap properties may make them attractive. However, fabrication of CZTS and CZTSSe films has proved challenging. Vacuum-based deposition, such as coevaporation and multilayer evaporation processes have been used, and have achieved device efficiencies of up to 6.7%. However, these processes do not scale well and may suffer from costly, low-throughput processing, variable spatial heterogeneity, and low yield.

In some examples, dry metal precursors may be deposited on a substrate followed by sulfurization. Sol-gel spin coating and electrodeposition of metal precursors have been used in these approaches, generally yielding maximum device efficiencies of 1.61% and 3.4%. Processes involving the deposition of metal precursors followed by sulfurization may have poor grain formation, delaminating due to volume expansion from the formation of metal sulfides from metals, and formation of binary compounds. Another approach has been to deposit a layer of CZTS nanocrystals, which may be annealed in a Se atmosphere to form CZTSSe.

Another approach has been to use a solution of hydrazine-based metal chalcogenide precursors to form CZTSSe directly. While this approach has improved efficiency of resulting devices, hydrazine is flammable, hepatotoxic, and carcinogenic, limiting the desirability of hydrazine-based approaches.

### SUMMARY

Embodiments of the present invention provide methods of forming a semiconductor film. Example methods may include combining a source of a first element, wherein the first element is selected from copper and silver, a source of a second element, wherein the second element is selected from zinc and cadmium, a source of a third element, wherein the third element is selected from tin, germanium, and silicon, and a source of a fourth element, wherein the fourth element is selected from selenium, sulfur, and tellurium in a liquid solvent to form a solution. The combining may include dissassociating at least one metal halide salt including said second or third element in said liquid solvent. Examples of methods may further include coating at least a portion of a substrate with the solution, and annealing the solution to form the semiconductor film.

In some examples, the fourth element is sulfur and the method further comprises selenizing the semiconductor film.

In some examples, the solvent comprises a polar solvent. In some examples, the solvent comprises a non-toxic solvent. In some examples, the solvent includes a solvent selected from dimethyl sulfoxide (DMSO), dimethylformamide (DMF), dichloromethane, tetrahydrofuran, ethyl acetate, propyl acetate, or any other acetate; acetone, methyl ethyl ketone, methyl amyl ketone, or any other ketone; acetonitrile, any polar aprotic solvent, ethanol, n-propanol, i-propanol, terpineol, or any other alcohol, ethylene glycol, propylene glycol, or any other diol, phenol, cresol, or any other phenolic solvent.

In some examples, the solution includes a co-solvent selected from monoethanolamine, diethanolamine, triethanolamine, monoethylamine, diethylamine, triethylamine, pyridine, or any other amine, hexane thiol, or any other thiol; ethane dithiol, hexane dithiol, or any other dithiol, diethyl ether, or any other ether.

In some examples, the at least one metal halide salt comprises Zn(II)chloride and Sn(II)chloride. In some examples, the first element is copper, the second element is zinc, the third element is tin, the fourth element is sulfur, and the semiconductor film comprises a CZTS or CZTSSe film.

In some examples, the combining includes combining Cu(II)acetate, Zn(II)chloride, Sn(II)chloride, and thiourea in the liquid solvent.

In some examples, the first element is copper and the combining includes combining a precursor having copper in a +2 oxidation state into the solution and the metal halide salt includes an element in a +2 oxidation state. The copper may be present in the semiconductor film in a +1 oxidation state and the element in the +2 oxidation state included in the metal halide salt may be present in the semiconductor film in a +4 oxidation state. The element in the +2 oxidation state included in the metal halide salt may be tin. The semiconductor film may comprise a Cu₂(Zn,Sn)SnS₄ film.

Examples of the present invention include methods of fabricating an electronic device. Examples methods may include forming a semiconductor film on a substrate. Forming the semiconductor film may include coating at least a portion of the substrate with a solution including sources of copper, zinc, tin, and either selenium or sulfur or a combination of selenium and sulfur, in a liquid solvent. The liquid solvent may include dimethyl sulfoxide. Methods may further include annealing the solution to yield the semiconductor film, and providing electrical contacts to the semiconductor film.

In some examples, the combining may include dissassociating at least one metal halide salt including said zinc or tin in said liquid solvent.

In some examples, the combining comprises mixing a first precursor including the copper in a +2 oxidation state and a second precursor including the tin in a +2 oxidation state in the liquid solvent. The semiconductor film may include copper in a +1 oxidation state and tin in a +4 oxidation state.

The electronic device may include a solar cell and methods may further include providing a transparent conductive material on the semiconductor film. Providing electrical contacts to the semiconductor film may include providing conductive contacts to the transparent conductive material.

The substrate in examples of the present invention may include a conductive-coated substrate and providing electrical contacts to the semiconductor film may include forming the semiconductor film on the conductive-coated substrate. The conductive-coated substrate comprises molebdynum-coated soda lime glass.

Embodiments of the present invention may further provide semiconductor films and electronic devices. Semiconductor films provided may include films having a nominal I₂-II-IV-VI₄ stoichiometry, and may include I₂-(II,IV)-IV-VI₄ films, including but not limited to CZTS and CZTSSe films.

### BRIEF DESCRIPTION OF THE DRAWINGS

FIG. 1 is a flowchart of an example method in accordance with embodiments of the present invention.

FIG. 2 is a schematic illustration of a solar cell formed in accordance with an embodiment of the present invention.

FIG. 3 illustrates resultant powder x-ray diffraction (PXRD) patterns of (a) as-synthesized CZTS/Mo/SLG; and (b) CZTSSe/Mo/SLG after selenization.

FIG. 4 is a scanning electron microscope (SEM) image of an example CZTSSe film and transparent conductive oxide (TCO) layer on a molebdynum contact.

FIG. 5 is a plot of the I-V characteristics of an example CZTSSe solar cell under AM1.5G illumination, as calibrated with a crystalline Si certified secondary reference cell calibrated with the official NREL primary reference cell.

FIG. 6 is a plot of the (αhv)² vs. hv for the solar cell, and the inset shows the transmission of the as-synthesized CZTS film described above on glass.

### DETAILED DESCRIPTION

Certain details are set forth below to provide a sufficient understanding of embodiments of the invention. However, it will be clear to one skilled in the art that embodiments of the invention may be practiced without various of these particular details. In some instances, well-known fabrication techniques, chemical components, additives, buffers, or device components have not been shown in detail in order to avoid unnecessarily obscuring the described embodiments of the invention.

Embodiments of the present invention generally include methods for forming semiconductor films having nominal I₂-II-IV-VI₄ stoichiometry, such as CZTS or CZTSSe, using a solution of sources of the I, II, IV, and VI elements in a liquid solvent. The sources may include precursor compounds, intermediate compounds, elemental forms of the elements, elements bound in a complex with the solvent or co-solvent, or combinations thereof. While embodiments of the present invention include methods for forming films having nominal I₂-II-IV-VI₄, in some examples, as will be described further below, the methods may produce films having a structure that may be more accurately described as I₂-(II,IV)-IV-VI₄, which films may have different site occupations that the nominal kesterite or stannnite crystal structure that describes traditional I₂-II-IV-VI₄ films. The solution of sources of elements in a liquid solvent, which may be a non-toxic solvent, may be coated onto a substrate. Precursors may be mixed in the solvent to form the solution and one or more of the precursors, including all of the precursors, may be soluble, inexpensive, and may be readily commercially available. For example, metal halide salts may be used as precursors, as will be described further below. Annealing and selenization may follow to form the desired semiconductor film.

Semiconductor films formed in accordance with embodiments of the present invention may generally have a thickness on the order of nanometers or microns. For example, a film may be less than 10 microns thick, less than 9 microns thick, less than 8 microns thick, less than 7 microns thick, less than 6 microns thick, less than 5 microns thick, less than 4 microns thick, less than 3 microns thick, less than 2 microns thick, less than 1 micron thick, less than 800 nanometers thick, or less than 600 nanometers thick, in some examples. In some examples, a film may be greater than 400 nanometers thick, greater than 600 nanometers thick, greater than 800 nanometers thick, greater than 1 micron thick, greater than 2 microns thick, greater than 3 microns thick, greater than 4 microns thick, greater than 5 microns thick, greater than 6 microns thick, greater than 7 microns thick, greater than 8 microns thick, greater than 9 microns thick, or greater than 10 microns thick. Other thicknesses may also be used.

Semiconductor films formed in accordance with embodiments of the present invention may have semiconductor properties. For example, examples of semiconductor films formed in accordance with embodiments of the present invention may have a band gap between valence and conduction bands of the material. Example band gaps of semiconductor films formed in accordance with embodiments of the present invention include those that are suitable for excitation with a solar source, including CZTS films with a bandgap of 1.45-151.eV. In some examples, a CZTS film according to the present invention may have a 1.48 eV band gap. CZTS or CZTSSe films formed in accordance with embodiments of the present invention may have a bandgap of between 1.45 and 1.51 eV, between 1.48 and 1.51 eV, between 1.45 and 1.49 eV, or between 1.48 and 1.49 eV. Other bandgaps may also be formed.

Semiconductor films formed in accordance with embodiments of the present invention may be films of quaternary chalcogenide compounds. Quaternary chalcogenide compounds may generally have a nominal I₂-II-IV-VI₄ stoichiometry, with the stoichiometry shown—2:1:1:4 ratio of the I, II, IV, and VI elements. However films formed herein, including CZTS or CZTSSe films, may have a stoichiometry that varies from the 2:1:1:4 ratio. In the notation ‘I’ refers to an element from Group 1B or 1A of the periodic table, where the groups refer to the CAS periodic table notation, or from any group and having an oxidation state of +1. ‘II’ refers to an element from Group 2B or 2A of the periodic table or from any group and having an oxidation state of +2. ‘IV’ refers to an element from Group 4A of the periodic table, or from any group and having an oxidation state of +4. ‘VI’ refers to an element from Group 6A of the periodic table, or from any group and having an oxidation state of −2. As will be described further below, in some examples films having a make-up of I₂-(II,IV)-IV-VI₄ may be formed, in that some element ‘IV’ may be present on crystal sites typically occupied by the ‘II’ element. That is, the element typically present at a +4 oxidation state, such as tin (Sn) may also be present at a +2 oxidation state in the semiconductor film.

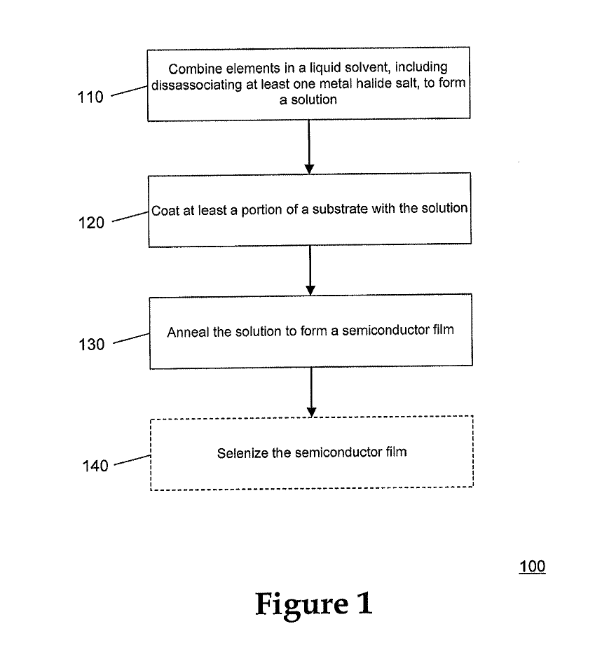

FIG. 1 is a flowchart of an example method in accordance with embodiments of the present invention. The method 100 includes block 110 where sources of elements may be combined in a liquid solvent to form a solution, including dissolving at least one metal halide salt in the liquid solvent. At block 120, at least a portion of a substrate may be coated with the solution, and at block 130, the solution may be annealed to form the semiconductor film. In some examples, at block 140, the film may be selenized to form, for example, a CZTSSe film. Blocks 110, 120, 130 and/or 140 may be repeated to build up a thickness of the film.

The elements combined in the liquid solvent may generally include an element for each of the ‘I’, ‘II’, ‘IV’, and ‘VI’ elements used to form a I₂-II-IV-VI₄ film, as described above. The elements need not be present in the liquid solvent in elemental form, but may be in a precursor or other intermediate compound. The sources of elements present in the liquid solution may include sources of first, second, third, and fourth elements. In the example of CZTS or CZTSSe films, the first element (e.g. ‘I’) may include copper (Cu), the second element (e.g. ‘II) may include zinc (Zn), the third element (e.g. ‘IV’) may include tin (Sn) and the fourth element (e.g. ‘VI’) may include sulfur (S) or selenium (Se), or combinations thereof. Generally, one or more sources of the elements may be provided in solution or may be placed in solution by mixing a precursor containing the element in the liquid solvent such that the element is made available in the solution. The elements accordingly may be available in the solution in a precursor compound, in an intermediate compound, in elemental form, or bound in a complex with the solvent or co-solvent. A separate source may be provided for individual ones of the elements, or in some examples a single source may be provided as a source for two or more of the elements.

The first element (e.g. ‘I’) combined in the liquid solvent may be selected from copper (Cu) and silver (Ag). The first element may generally be a metal capable of having an oxidation state of +1 in the semiconductor film. Any number of elements capable of having an oxidation state of +1 in the semiconductor film may be used. In some examples, only Cu is available as the first element in the solution. In some examples, only Ag may be available as the first element in the solution. In other examples, Cu and Ag element are both provided in the liquid solution. In still other examples, other elements may be provided that may have an oxidation state of +1 in the semiconductor film including, but not limited to, sodium (Na), potassium (K), rubidium (Rb), or combinations thereof. Generally, the predominant source of the Group I or oxidation state of +1 element for the semiconductor film is Cu, Ag, or combinations thereof. One percent or less of the ‘I’ sites of the semiconductor film in some examples may be provided by other elements such as, but not limited to sodium (Na), potassium (K), rubidium (Rb), or combinations thereof, and accordingly smaller amounts of these elements may be provided in the liquid solution. In some examples, as will be described further below, one or more of the ‘I’ elements in the solution may be provided from the substrate. For example, Na may diffuse into the solution or into the final film from a source in the substrate.

Sources of the first elements include precursors such as copper(II)acetate, which may be provided as hydrated copper(II)acetate Cu(CH₃COO)₂.H₂O. Copper(II)acetate may have copper in a +2 oxidation state. Other sources (e.g. precursors) may also be used suitable for providing the first element in the liquid solvent. The precursor need not contain the element in the +1 oxidation state. Rather, the source of the first element may include the element in a different oxidation state but the element may nonetheless be present in the semiconductor film after reacting with other sources in the solution in a +1 oxidation state. For example, copper(II)acetate includes copper in a +2 oxidation state, however, as will be described further below, the copper(II)acetate precursor may participate in reactions that result in copper in a +1 oxidation state being incorporated into a semiconductor film.

The second element (e.g. ‘II’) may include zinc (Zn). In some examples, Zn is a predominant source of the second element, but less than 1% of the ‘II’ in the semiconductor film may be provided by one or more other elements capable of having an oxidation state of +2 in the semiconductor film, such as but not limited to, cadmium, mercury, calcium, magnesium, or combinations thereof. The second element may generally be an element from Group II of the periodic table or from any group and having an oxidation state of +2.

Sources of the second element in the solution include metal halide salts, such as chloride salts, bromide salts, iodide salts, or mixed chloride salts including a halide and an organic ligand. Hydrated metal halide salts may be used. One example is zinc(II)chloride, which may be provided as ZnCl₂. Other sources (e.g. precursors) may be used suitable for providing the second element in the liquid solvent. The precursor need not provide the second element in a +2 oxidation state, rather the second element may be in a +2 oxidation state in the semiconductor film. In some examples, Sn may be provided in the solution and may react to be included in the semiconductor film in both a +2 and +4 oxidation state. In some examples, sources including Sn may be provided as a source of at least some of the second element and films of, e.g. Cu₂(Zn,Sn)Sn(S,Se)₄ may be formed.

The third element (e.g. ‘IV’) may be selected from tin (Sn), germanium (Ge), and silicon (Si). In some examples, only Sn is provided as the third element. In some examples, only Ge is provided as the third element. In some examples, only Si is provided as the third element. In some examples, both Sn and Ge may be provided in the liquid solution. In some examples, both Sn and Ge may be provided in the liquid solution. In some examples, both Ge and Si may be provided in the liquid solution. In some examples Sn, Ge, and Si may be provided in the liquid solution. In other examples, Sn,Ge, or Si, or any combinations thereof may be the dominant source of a ‘IV’ element, and less than one percent may be provided by another element in Group IV of the periodic table or capable of having an oxidation state of +4 in the semiconductor film. The third element may generally be a metal capable of having an oxidation state of +4 in the semiconductor film.

Sources of the third element in the solution include metal halide salts, such as chloride salts, bromide salts, iodide salts, or mixed chloride salts including a halide and an organic ligand. Hydrated metal halide salts may be used. One example is tin(II)chloride, which may be provided as hydrated tin(II)chloride, SnCl₂.2H₂O. Tin(II)chloride may provide tin having a +2 oxidation state in the precursor. Other precursors may be used suitable for providing the third element in the liquid solvent. The precursor need not provide the third element in a +4 oxidation state, rather, the third element may be in a +4 oxidation state in the semiconductor film once formed.

The fourth element (e.g. ‘VI’) may be a chalcogenide, and may be selected from oxygen (0), sulfur (S), selenium (Se), tellerium (Te), polonium (Po), and combinations thereof. In some examples, the fourth element may be selected from sulfur (S), selenium (Se), and tellurium (Te). The fourth element may generally be selected from Group VI of the periodic table or any element capable of having an oxidation state of −2 in the semiconductor film. Sources (e.g. precursors) that may be used to provide the fourth element include thiourea SC(NH₂)₂, thioacetimide, selenourea, or elemental S or elemental Se dissolved in a solvent such as dimethylsulfoxide (DMSO). Other suitable solvents will be described further below.

Combining sources of the elements, such as in block 110 of FIG. 1, may include adding precursors containing the elements to the liquid solvent. In some examples, one source may contain more than one of the elements for combining into solution. In other examples, one or more sources of the elements may be provided in solution, and sources (e.g. precursors) containing others of the elements may be added to the solution. Combining the elements may include dissassociating at least one metal halide salt including one of the elements in the liquid solvent Dissassociating the metal halide salt may result in the metal elements being combined into the solution.

The ratio of elements provided in the solution may generally be selected such that sufficient amounts are provided to form the stoichiometric composition of the semiconductor film of interest. To improve the electronic properties of the semiconductor film, in some examples, the amount of elements made available in the solution are selected such that the semiconductor film may be considered copper-poor, in that the copper ratio may be less than suggested by the 2:1:1:4 nominal stoichiometry.

In embodiments of the present invention, in block 110 of FIG. 1, the method may include combining a source of a first element, the first element being selected from copper and silver, a source of a second element, the second element being selected from zinc and cadmium, a source of a third element, the third element selected from tin and germanium, and a source of a fourth element, the fourth element being selected from selenium and sulfur in a liquid solvent to form a solution. The combining may include dissassociating at least one metal halide salt including said second or third element in said liquid solvent.

Embodiments of the present invention may make use of a non-toxic liquid solvent. For example, dimethyl sulfoxide (DMSO) may be used as the liquid solvent. Other suitable solvents include, but are not limited to dimethylformamide (DMF), dichloromethane, tetrahydrofuran, ethyl acetate, propyl acetate, any acetate, acetone, methyl ethyl ketone, methyl amyl ketone, or any other ketone, acetonitrile, any polar aprotic solvent, ethanol, n-propanol, i-propanol, terpineol, or any other alcohol, ethylene glycol, propylene glycol, or any other diol, phenol, cresol, or any other phenolic solvent. Combinations of these solvents may also be used. Generally, one of the solvents provided may have sufficient polarity to dissassociate metal halide salt precursors. Further, solvents with sufficient polarity which do not themselves dissassociate to create OH⁻ or H⁺, may be preferred in some embodiments. Solvents that themselves dissassociate to form OH may not be preferred because OH may be found in the same column of the periodic table as sulfur and selenium, which may be disadvantageous as the OH may interfere with the formation of the semiconductor film containing sulfur or selenium.

In some examples, a co-solvent may be included along with the solvent or solvents. The co-solvent may increase solubility of one or more precursors in the solution. In some examples, the co-solvent may be monoethanolamine, diethanolamine, triethanolamine, monoethylamine, diethylamine, triethylamine, pyridine, or any other amine, hexane thiol, or any other thiol; ethane dithiol, hexane dithiol, or any other dithiol, diethyl ether, or any other ether. The co-solvent may be provided in addition to a solvent or combinations of solvents described above. In some embodiments, DMSO plus ethanolamine, diethylamine, triethylamine, ethers, or combinations thereof may be used as the liquid solvent.

Referring back again to FIG. 1, in block 120, at least a portion of a substrate may be coated with the solution. Any of a variety of substrates may be used, including but not limited to glass or molybdenum/soda lime glass (Mo/SLG). The substrate may be selected for compatibility with a desired final electronic device, examples of which are described further below. The coating may be performed by spin coating or other solution deposition techniques may be used to apply the solution to at least a portion of the substrate. Generally, the solution may be coated across an entire substrate, or in some embodiments may be contained to a particular section of the substrate for localized formation of the semiconductor film.

In block 130 of FIG. 1, the solution may be annealed to form the semiconductor film. Annealing may include subjecting the solution, and in many examples the substrate, to an elevated temperature to promote or facilitate a chemical reaction to produce the semiconductor film, e.g. CZTS or CZTSSe, using at least a portion of the species in the solution. Without being bound by theory, in one example where Cu(II)acetate is used as a precursor to provide a source of the Cu element, zinc(II)chloride is used as a precursor to provide a source of the Zn element, tin(II)chloride is used as a precursor to provide a source of the Sn element, and thiourea is used as a precursor to provide a source of the S element, a reaction which may occur to produce a CZTS film may be given as follows:

2Cu(CH₃COO)₂.H₂O+ZnCl₂+SnCl₂.2H₂O+4SC(NH₂)₂→Cu₂ZnSnS₄ (s)+4HCl (g)+4H₂NCN (g)+4CH₃COOH (g)+3H₂O (g).

However, the actual reaction used and the gaseous products produced may vary. Note that the copper present in the Cu(II)acetate precursor may have a +2 oxidation state, however in the semiconductor film of CZTS, the copper may have a +1 oxidation state. The tin present in the tin(II)chloride precursor may have a +2 oxidation state. However, in the semiconductor film of CZTS, the tin may have a +4 oxidation state. Accordingly, during the reaction provided above, a redox reaction may occur where some or all of the copper may reduce from a +2 to a +1 oxidation state and some or all of the tin may shift from a +2 to a +4 oxidation state. In this manner, the final CZTS semiconductor film may contain tin in both a +2 and +4 oxidation state. Generally, a Group IV element having a +2 oxidation state may be used in a source (e.g. precursor) to form a semiconductor film having the Group IV element in the +4 oxidation state. The shift from the +2 to the +4 oxidation state may allow for the reduction of copper during the reaction from the +2 to the +1 oxidation state. In this manner, copper having a +2 oxidation state may be used in a precursor. Copper in the +2 oxidation state may have a greater soluability and stability than copper in a +1 oxidation state. In this manner, the use of a stable copper precursor such as Cu(II)acetate may be facilitated by the use of a precursor including tin in the +2 oxidation state. As the tin shifts from a +2 to +4 oxidation state, the copper may shift from the +2 to +1 state.

Annealing may generally occur at a temperature between 150 and 800° C., above 150° C. in some examples, above 200° C. in some examples, above 250° C. in some examples, above 300° C. in some examples, above 350° C. in some examples, above 400° C. in some examples, above 450° C. in some examples, above 500° C. in some examples, above 550° C. in some examples, above 600° C. in some examples, above 650° C. in some examples, above 700° C. in some examples, above 750° C. in some examples, and above 800° C. in some examples. Any suitable method may be used to heat the solution during the annealing including, but not limited to, use of a hot plate, heat lamp, furnace, or other heating device.

The coating and annealing processes may be repeated several times to build up additional thickness of the semiconductor film. Any number of repetitions may generally be used including, but not limited to 1, 2, 3, 4, 5, 6, 7, 8, 9, 10, 11, 12, 13, 14, 15, 16, 17, 18, 19, or 20 repetitions.

In some examples, the semiconductor film may be selenized in block 140 of FIG. 1 to form a CZTSSe film. Selenization may occur in any of a variety of ways, including annealing under Se vapor, which may occur during the above-described anneal, or may occur after the initial anneal to form the semiconductor film. The Se vapor may be produced, for example, by annealing in an anneal chamber containing Se pellets. During selenization, generally some Se atoms may substitute for S atoms in the CZTS film, yielding a CZTSSe film. Following selenization, the S/(S+Se) ration in the film may be between about 0.6 and 0.8. In some examples, the ratio may be about 0.7. The selenization step may also be repeated as described above with the coating an annealing processes, or in some examples a single selenization process may occur following several repetitions of the coating and annealing processes to selenize the semiconductor film at its final thickness.

Films formed in accordance with embodiments of the present invention may generally be used in any device that may utilize a thin film semiconductor. Examples of devices include, but are not limited to, solar cells, light emitting diodes, field effect transistors, solid state lasers, radiation adsorbing or emitting layers for electromagnetic shielding or stealth technology.

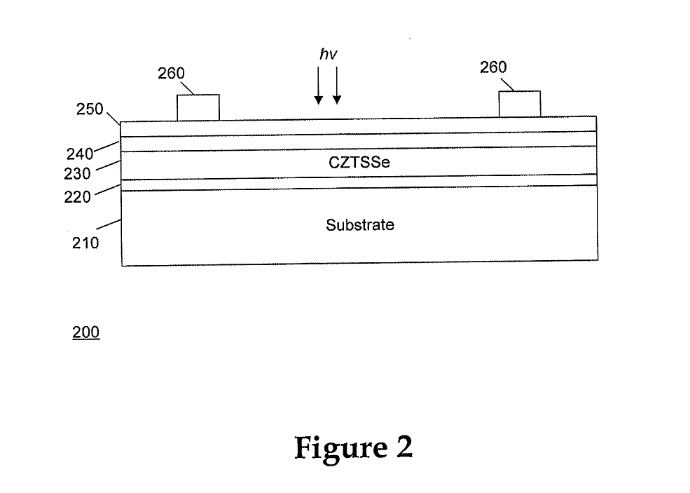

Generally, methods of fabricating an electronic device according to embodiments of the present invention, including methods of fabricating the solar cell 200 of FIG. 2, including forming a semiconductor film on a substrate, using an embodiment of the method for forming a semiconductor film described above. Electrical contact may then be made to the semiconductor film sufficient to allow a voltage or current to be applied to or detected across the semiconductor film. In this manner, the electrical properties of the semiconductor film may be utilized in an electronic device.

FIG. 2 is a schematic illustration of a solar cell formed in accordance with an embodiment of the present invention. The solar cell 200 may include a substrate 210, a back contact 220, a CZTS or CZTSSe adsorber 230, a semiconductor 240, a window layer 250, and contacts 260. The back contact 220 and contacts 260 are conductive and are positioned such that a voltage and/or current may be applied and/or detected across the CZTS or CZTSSe adsorber layer 230. It is to be understood that the design of electronic device using semiconductor films described herein is quite flexible, and a variety of configurations are possible for electrical contact to the semiconductor film.

As mentioned above, the substrate 210 may be implemented using any substrate suitable for supporting a semiconductor film described herein. Examples include, but are not limited to, glass including soda lime glass, silicon, polymer, or plastic substrates. While the substrate 210 is depicted as a flat substrate, in other examples patterned or curved substrates may be used, including substrates having other mechanical structure or circuits already fabricated on the substrate for integration with the films described herein.

The back contact 220 may be implemented as a conductive coating to the substrate 210, such as a molybdenum coating on a soda lime glass substrate. In other examples, a different conductive material may be used to implement the back contact 220, including but not limited to aluminum or copper. The back contact 220 is depicted as extending across the substrate 210, but in other examples may be a patterned contact and may not extend across the entire interface between the substrate 210 and the semiconductor film 220. In other examples, the back contact 220 may be made on an opposite side of the semiconductor film 220, such that it is not at the “back.”

The CZTS or CZTSSe adsorber 230 may be formed using the methods described above for forming semiconductor films. Generally, in the solar cell 200 of FIG. 2 or other examples of electronic device, the CZTS or CZTSSe film formed in accordance with embodiments of the present invention may function as a p-type semiconductor material.

The semiconductor 240 may be implemented as an n-type semiconductor material to form a p-n junction with the CZTS or CZTSSe film 230. The semiconductor 240 may be implemented as any semiconducting material suitable for use in a solar cell, including but not limited to cadmium sulfide (CdS). The semiconductor 240 may be formed on the CZTS or CZTSSe adsorber 230 using any fabricating technique, including but not limited to chemical bath deposition, sol gel techniques, metalorganic chemical vapor deposition, sputtering, spraying the CZTS or CZTSSe film with CdS precursors, screen printing, or combinations thereof.

The window layer 250 may be implemented by any suitable material or material combinations that yield a transparent, conductive film. Transparent here is used to indicate the window layer 250 may pass a sufficient amount of light through to the semiconductor 240 and CZTS or CZTSSe adsorber 230 to allow for operation of the device as a solar cell 200. Accordingly, the window layer 250 need not be 100 percent transparent, but the amount of light passed by the window layer 250 will be related to the device's performance as a solar cell. Materials used to implement the window layer 250 include, but are not limited to, zinc oxide such as i-ZnO, and indium tin oxide (ITO). A combination of these material layers may be used. The window layer 250 may be formed using any suitable fabrication technique including but not limited to evaporation, physical vapor deposition, sputtering, or combinations thereof.

The contacts 260 may be implemented using any conductive material or combinations of conductive materials including, but not limited to aluminum, copper, nickel, or combinations thereof. The contacts 260 may be patterned using any suitable fabrication techniques including but not limited to techniques for deposition, lithography, and etching. Examples include, evaporating or otherwise depositing through a shadow mask, sputtering, lithographically-patterning and wet or dry etching.

Some advantages of embodiments of the present invention are discussed herein to aid in understanding the embodiments and examples described. The advantages discussed herein are not intended to be limiting. Not all examples of the present invention exhibit all described advantages, and some examples may not exhibit any of the described advantages. Nonetheless, examples of the invention described herein may provide thin film semiconductors from inexpensive, non-toxic, and relatively abundant starting materials. Moreover, the electronic quality of the semiconductor films produced according to examples of the present invention may be of relatively good quality. Still further, examples of the present invention may be readily scaled-up for commercial manufacturing, and may produce thin films using nearly all of the starting metal salts.

### EXAMPLES

Examples of semiconductor film and electronic device fabrication are described below in accordance with embodiments of the present invention, and some experimental results are presented. It will be apparent to those skilled in the art that many modifications, both to materials and methods, may be practiced without departing from the scope of the disclosure.

Semiconductor Film Formation

A coating solution was prepared to form a CZTS film by dissolving 0.8 mmol of Cu(CH₃COO)₂.H₂O (99.99%, obtained from Aldrich), 0.56 mmol of ZnCl₂ (99.1%, obtained from Mallinckrodt Baker), 0.55 mmol of SnCl₂.2H₂O (99.995% obtained from Aldrich), and 2.64 mmol of thiourea (99%, obtained from Aldrich) into 0.7 mL dimethyl sulfoxide (DMSO) (99%, obtained from Aldrich) at room temperature. CZTS films were obtained by spin coating the coating solution on a Mo/SLG substrate followed by annealing at 580° C. on a hot plate. The spin coating was performed at 1500 rpm for 1 minute. The annealing was performed for 2.5 minutes inside of a glove box with O₂ and H₂O at less than 5 ppm. The coating and annealing steps were repeated seven times to obtain a 1.4 μm thick CZTS film. The overall reaction occurring may be given as:

2Cu(CH₃COO)₂.H₂O+ZnCl₂+SnCl₂.2H₂O+4SC(NH₂)₂→Cu₂ZnSnS₄ (s)+4HCl (g)+4H₂NCN (g)+4CH₃COOH (g)+3H₂O (g).

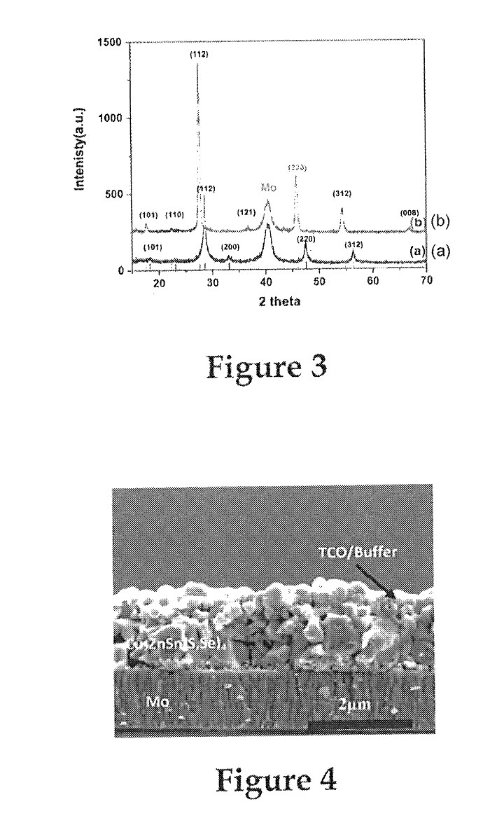

FIG. 3 illustrates resultant powder x-ray diffraction (PXRD) patterns of (a) as-synthesized CZTS/Mo/SLG; and (b) CZTSSe/Mp/SLG after selenization.

Solar Cell Fabrication

The CZTS film described above was selenized to form Cu₂ZnSn(SₓSe₁₋ₓ)₄ (CZTSSe) adsorbers by annealing under Se vapor at 500° C. for 20 minutes inside a graphite box in a tube furnace with flowing Ar (10 sccm). The Se vapor was provided using selenium pellets (99.99% obtained from Aldrich). FIG. 3(b) illustrates the PXRD pattern of the resultant selenized semiconductor film.

Energy-dispersive X-ray spectroscopy (EDX) was used to estimate the metal stoichiometries of Cu/(Zn+Sn) and Zn/Sn in the CZTSSe film to be 0.79 and 1.13, respectively.

After cooling down to room temperature under flowing Ar, the CZTSSe/Mo/SLG substrate was immediately immersed in a solution for chemical bath deposition of CdS. The bath was maintained at 65° C. and contained 183 ml of deionized H₂O, 31.25 mL of NH₄OH (ACS reagent, obtained from Aldrich), 25 ml of 0.015 M CdSO₄ (99%, obtained from Aldrich) solution, and 12.5 mL of 1.5M thiourea (99%, obtained from Aldrich) in deionized water. The chemical bath deposition was initiated by addition of the thiourea, whereupon the substrate was immersed in the bath immediately after thiourea addition. The CdS was deposited fro 17 minutes to yield an approximately 50 nm thick CdS layer. 50 nm of i-ZnO followed by 250 nm of ITO were deposited by RF magnetron sputtering. Ni followed by Al was thermally evaporated through a shadow mask to form top electrical contacts. FIG. 4 is a scanning electron microscope (SEM) image of the CZTSSe film and transparent conductive oxide (TCO) layer on a molebdynum contact. The top contacts are not shown in FIG. 4.

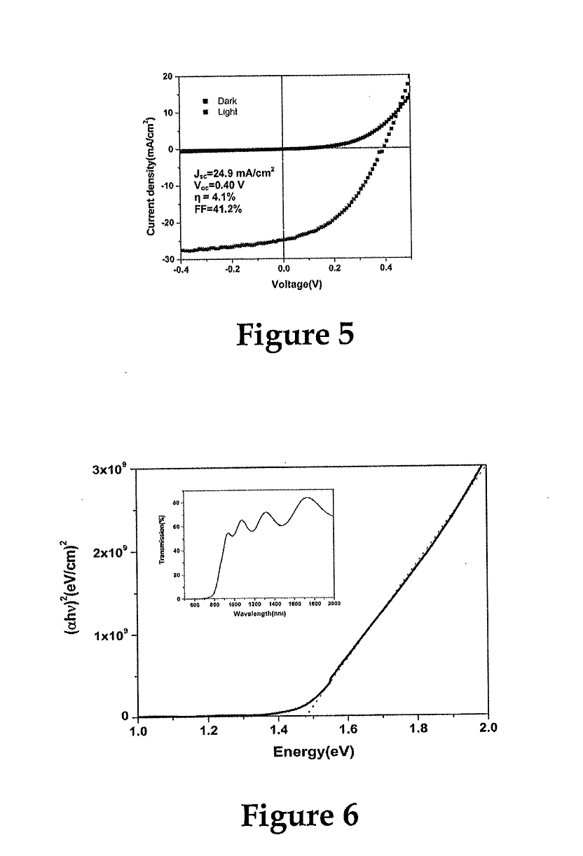

FIG. 5 is a plot of the I-V characteristics of the CZTSSe solar cell, under AM1.5G illumination, as calibrated with a crystalline Si certified secondary reference cell calibrated with the official NREL primary reference cell. The power conversion efficiency (η) was 4.1% with V_{oc}=0.4 V, J_{sc}=24.9 mA/cm², and FF=41.2%. A shunt resistance of 560Ω, a series resistance of 8.3Ω, and a diode quality factor of 2.8 were measured. The optical gap of the CZTSSe adsorber layer estimated from measured quantum efficiency data using linear extrapolation was 1.07 eV.

FIG. 6 is a plot of the (αhv)² vs. hv for the solar cell, and the inset shows the transmission of the as-synthesized CZTS film described above on glass. The estimated band gap energy is 1.48 eV assuming negligible scattering and reflection.

From the foregoing it will be appreciated that, although specific embodiments of the invention have been described herein for purposes of illustration, various modifications may be made without deviating from the spirit and scope of the invention.

What is claimed is:

1. A method of forming a semiconductor film, the method comprising:
combining a source of a first element, wherein the first element is selected from copper and silver, a source of a second element, wherein the second element is selected from zinc and cadmium, a source of a third element, wherein the third element is selected from tin, germanium, and silicon, and a source of a fourth element, wherein the fourth element is selected from selenium, sulfur, and tellurium in a liquid solvent to form a solution, wherein said combining comprises dissassociating at least one metal halide salt including said second or third element in said liquid solvent;
coating at least a portion of a substrate with the solution; and
annealing the solution to form the semiconductor film.

2. The method of claim 1, wherein the fourth element is sulfur and the method further comprises selenizing the semiconductor film.

3. The method of claim 1, wherein the solvent comprises a polar solvent.

4. The method of claim 1, wherein the solvent comprises a non-toxic solvent.

5. The method of claim 1, wherein the solvent includes a solvent selected from dimethyl sulfoxide (DMSO), dimethylformamide (DMF), dichloromethane, tetrahydrofuran, ethyl acetate, propyl acetate, or any other acetate; acetone, methyl ethyl ketone, methyl amyl ketone, or any other ketone; acetonitrile, any polar aprotic solvent, ethanol, n-propanol, i-propanol, terpineol, or any other alcohol, ethylene glycol, propylene glycol, or any other diol, phenol, cresol, or any other phenolic solvent.

6. The method of claim 5, wherein the solution includes a co-solvent selected from monoethanolamine, diethanolamine, triethanolamine, monoethylamine, diethylamine, triethylamine, pyridine, or any other amine, hexane thiol, or any other thiol; ethane dithiol, hexane dithiol, or any other dithiol, diethyl ether, or any other ether.

7. The method of claim 1 wherein the at least one metal halide salt comprises Zn(II)chloride and Sn(II)chloride.

8. The method of claim 1, wherein the first element is copper, the second element is zinc, the third element is tin, the fourth element is sulfur, and the semiconductor film comprises a CZTS or CZTSSe film.

9. The method of claim 8, wherein said combining further comprises combining Cu(II)acetate, Zn(II)chloride, Sn(II)chloride, and thiourea in the liquid solvent.

10. The method of claim 1, wherein the first element is copper and the combining comprises combining a precursor having copper in a +2 oxidation state into the solution and the metal halide salt includes an element in a +2 oxidation state.

11. The method of claim 10, wherein the copper is present in the semiconductor film in a +1 oxidation state and the element in the +2 oxidation state included in the metal halide salt is present in the semiconductor film in a +4 oxidation state.

12. The method of claim 11, wherein the element in the +2 oxidation state included in the metal halide salt is tin.

13. The method of claim 1, wherein the semiconductor film comprises a Cu₂(Zn,Sn)SnS₄ film.

14. A method of fabricating an electronic device, the method comprising:
forming a semiconductor film on a substrate, including:
coating at least a portion of the substrate with a solution including sources of copper, zinc, tin, and either selenium or sulfur or a combination of selenium and sulfur, in a liquid solvent, wherein the liquid solvent includes dimethyl sulfoxide;
annealing the solution to yield the semiconductor film; and
providing electrical contacts to the semiconductor film.

15. The method of claim 14, wherein said combining comprises dissassociating at least one metal halide salt including said zinc or tin in said liquid solvent.

16. The method of claim 14, wherein said combining comprises mixing a first precursor including the copper in a +2 oxidation state and a second precursor including the tin in a +2 oxidation state in the liquid solvent.

17. The method of claim 16, wherein the semiconductor film includes copper in a +1 oxidation state and tin in a +4 oxidation state.

18. The method of claim 14, wherein the electronic device comprises a solar cell and wherein the method further comprises providing a transparent conductive material on the semiconductor film, and wherein said providing electrical contacts to the semiconductor film includes providing conductive contacts to the transparent conductive material.

19. The method of claim 18, wherein the substrate comprises a conductive-coated substrate and wherein said providing electrical contacts to the semiconductor film includes forming the semiconductor film on the conductive-coated substrate.

20. The method of claim 19, wherein the conductive-coated substrate comprises molebdynum-coated soda lime glass.
